(19) United States
(12) Patent Application Publication
(10) Pub. No.: US 2021/0205949 A1
(43) Pub. Date: Jul. 8, 2021

(54) APPARATUS AND METHOD FOR DOUBLE-SIDE POLISHING WORKPIECE

(71) Applicant: SUMCO CORPORATION, Tokyo (JP)

(72) Inventors: Mami KUBOTA, Tokyo (JP); Eisuke NONAKA, Tokyo (JP); Tetsurou TANIGUCHI, Tokyo (JP); Keiichi TAKANASHI, Tokyo (JP)

(73) Assignee: SUMCO CORPORATION, Tokyo (JP)

(21) Appl. No.: 17/056,547

(22) PCT Filed: Feb. 21, 2019
(86) PCT No.: PCT/JP2019/006475

§ 371 Date: Nov. 18, 2020

(30) Foreign Application Priority Data
May 22, 2018 (JP) 2018-098061

(51) Int. Cl. B24B 37/08

(52) U.S. Cl. CPC B24B 37/08

(57) ABSTRACT

Provided are a double-side polishing apparatus and a double-side polishing method which can terminate double-side polishing of a workpiece so that the workpiece will have a desired shape even when double-side polishing of the workpiece is performed repeatedly. The control means determines, from a reference time point determined based on the amplitude of the change of the temperature of the carrier plate, an offset time for the next batch during which additional double-side polishing is performed; and terminates double-side polishing after a lapse of the determined offset time from the reference time point. The offset time is determined based on a predicted value of the shape index of the workpiece in the next batch, predicted from the actual value of the shape index of the workpiece having been double-side polished in one or more previous batches and from difference of the offset time between batches.

### TECHNICAL FIELD

This disclosure relates to a double-side polishing apparatus and a double-side polishing method for a workpiece.

### BACKGROUND

In the production of semiconductor wafers such as a silicon wafer, which is a typical example of a workpiece to be polished, double-side polishing for simultaneously polishing the front and back surfaces of the wafer is generally used to achieve more accurately controlled flatness quality and surface roughness quality of the wafer. The shape required of a semiconductor wafer (primarily the flatness required of the whole surface and the periphery of the wafer) varies depending on the uses. It is necessary to determine the target amount of polishing removal of wafers depending on the requirements, and to accurately control the amount of polishing removal.

In particular, in recent years, due to miniaturization of semiconductor devices and increase in the diameter of semiconductor wafers, higher flatness is increasingly required for semiconductor wafers subjected to light exposure. Against this background, techniques for accurately controlling the amount of polishing on wafers are strongly desired. In this regard, for example, PTL 1 (JP 2002-254299 A) discloses a method of controlling the amount of polishing on a wafer in accordance with the drop in the driving torque of polishing plates of a double-side polishing apparatus during polishing.

However, in the method disclosed by PTL 1, the change in the polishing plate torque poorly responds to the change in the amount of polishing removal of a wafer, and it is difficult to determine the correlation between the amount of change in torque and the amount of polishing removal of the wafer. Further, the method detects a great torque change occurring when a carrier plate for holding wafers and polishing plates come in contact with each other, and determines the time point as a polishing termination point. Therefore, the amount of polishing removal cannot be determined in a state where the carrier plate and the polishing plate are not in contact with each other. This has been a problem.

To address this problem, JP 5708864 B (PTL 2) discloses a double-side polishing apparatus which, with a focus on the periodic change of the temperature of a carrier plate in synchronicity with the rotation of the carrier plate in the early stage of double-side polishing (see FIG. 7 and FIG. 8 of PTL 2), controls the amount of polishing removal of a workpiece based on the amplitude of the temperature of the carrier plate.

FIG. 1 illustrates a double-side polishing apparatus disclosed in PTL 2. A double-side polishing apparatus 100 depicted in the figures includes a carrier plate 3 in which one or more retainer openings 2 each for retaining a workpiece 1 to be polished are formed, and an upper polishing plate 5 and a lower polishing plate 4 that make a pair, between which the carrier plate 3 is sandwiched. The retainer openings 2 of the carrier plate 3 are eccentric to the center of the carrier plate 3 and are configured to be rotatable by the sun gear 7 and the internal gear 8. Further, polishing pads 6 are attached on the surfaces of the upper and lower polishing plates 4 and 5, which face each other.

The double-side polishing apparatus 100 also includes a temperature measurement means 9 constituted by an infrared sensor or the like that measures the temperature of the carrier plate 3 and a controller 10 which controls double-side polishing of a workpiece.

As described above, in the double-side polishing apparatus 100 disclosed in PTL 2, the temperature of the carrier plate 3, which is measured using the temperature measurement means 9, periodically changes in synchronicity with the rotation of the carrier plate 3 in the early stage of double-side polishing. FIG. 2 illustrates the amplitude in the change of the temperature of the carrier plate 3 which has been measured using the temperature measurement means 9. The amplitude is smaller as the thickness of the workpiece 1 approximates the thickness of the carrier plate 3, and is zero when the thickness of the workpiece 1 becomes equal to the thickness of the carrier plate 3.

In the double-side polishing apparatus 100 described in PTL 2, the controller 10 controls the amount of polishing removal of the workpiece 1 so that double-side polishing is terminated based on the above amplitude in the temperature change of the carrier plate 3. This is how the workpiece 1 having high flatness and a desired shape is obtained according to PTL 2.

### CITATION LIST

### Patent Literature

PTL 1: JP 2002-254299 A

PTL 2: JP 5708864 B

### SUMMARY

### Technical Problem

The inventors of this disclosure performed double-side polishing on a workpiece 1, specifically a silicon wafer, while controlling the amount of polishing removal based on the amplitude in the temperature change of the carrier plate 3 using the double-side polishing apparatus 100 disclosed in PTL 2. As a result, a workpiece 1 having a desired shape was obtained when double-side polishing was performed using a freshly produced carrier plate having high flatness. However, it was found that the shape of the workpiece 1 having been double-side polished is gradually deviated from the desired shape and is worsen as double-side polishing is repeated.

It could therefore be helpful to provide an apparatus and a method for double-side polishing a workpiece, which make it possible to terminate double-side polishing of the workpiece so that the workpiece has a desired shape even when double-side polishing is repeatedly performed.

### Solution to Problem

[1] An apparatus for double-side polishing a workpiece, including a carrier plate in which one or more retainer openings each for retaining a workpiece to be polished are formed, and an upper polishing plate and a lower polishing plate that make a pair between which the carrier plate is sandwiched, comprising:

a temperature measurement means for measuring a temperature of the carrier plate; and

a control means for controlling an amount of polishing removal of the workpiece,

wherein the control means determines, from a reference time point for determining a termination point of double-side polishing determined based on amplitude of change of temperature of the carrier plate measured using the temperature measurement means, an offset time for a next batch that is a time during which additional double-side polishing is performed; and terminates double-side polishing of the workpiece after a lapse of the determined offset time from the reference time point, and

the offset time is determined based on a predicted value of a shape index of the workpiece to be double-side polished in the next batch, predicted from an actual value of a shape index of the workpiece having been double-side polished in one or more previous batches and from difference of the offset time between batches.

[2] The apparatus for double-side polishing a workpiece, according to [1] above, wherein the predicted value is given by the following equation (1):

Y=AX₁+BX₂+C (1),

where the predicted value is Y, the actual value of the shape index is X₁, the difference of the offset time is X₂, and A, B, and C are constants.

[3] The apparatus for double-side polishing a workpiece, according to [2] above, wherein an average of actual values of shape indices of the workpiece, obtained in three batches up to three batches ago is X₁; and an average of the differences of the offset time between batches is X₂.

[4] The apparatus for double-side polishing a workpiece, according to [1] to [3] above, wherein the reference time point is a time point when the amplitude of the temperature change of the carrier plate becomes zero.

[5] The apparatus for double-side polishing a workpiece, according to [1] to [3] above, wherein the reference time point is a time point before when the amplitude of the temperature change of the carrier plate becomes zero.

[6] The apparatus for double-side polishing a workpiece, according to [1] to [5] above, wherein the shape index is a GBIR.

[7] A method of double-side polishing a workpiece, including sandwiching, between an upper polishing plate and a lower polishing plate, a carrier plate in which one or more retainer openings each for retaining a workpiece to be polished are formed, with one or more workpieces being held in the carrier plate; and simultaneously polishing both surfaces of the workpieces by relatively rotating the carrier plate and the upper and lower polishing plates, comprising:

measuring temperature of the carrier plate during double-side polishing, thereby determining a reference time point for determining a termination point of double-side polishing determined based on amplitude of change of the temperature measured; and

determining, from the reference time point, an offset time for a next batch that is a time during which additional double-side polishing is performed, and terminating double-side polishing of the workpieces after a lapse of the determined offset time from the reference time point,

wherein the offset time is determined based on a predicted value of a shape index of the workpiece to be double-side polished in the next batch, predicted from an actual value of a shape index of the workpiece having been double-side polished in one or more previous batches and from difference of the offset time between batches.

[8] The apparatus for double-side polishing a workpiece, according to [7] above, wherein the predicted value is given by the following equation (2):

Y=AX₁+BX₂+C (2),

where the actual value of the shape index is X₁, the difference of the offset time is X₂, and A, B, and C are constants.

[9] The method of double-side polishing a workpiece, according to [8] above, wherein an average of actual values of shape indices of the workpiece, obtained in three batches up to three batches ago is X₁; and an average of the differences of the offset time between batches is X₂.

[10] The method of double-side polishing a workpiece, according to [7] to [9] above, wherein the reference time point is a time point when the amplitude of the temperature change of the carrier plate becomes zero.

[11] The method of double-side polishing a workpiece, according to [7] to [9] above, wherein the reference time point is a time point before when the amplitude of the temperature change of the carrier plate becomes zero.

[12] The method of double-side polishing a workpiece, according to [7] to [11] above, wherein the shape index is a GBIR.

### Advantageous Effect

According to this disclosure, even when double-side polishing of the workpiece is performed repeatedly, double-side polishing of a workpiece can be terminated so that the workpiece will have a desired shape.

### BRIEF DESCRIPTION OF THE DRAWINGS

In the accompanying drawings:

FIG. 1 is a diagram illustrating the double-side polishing apparatus disclosed in PTL 2;

FIG. 2 is a diagram illustrating the amplitude of the temperature change of a carrier plate in the early stage of double-side polishing;

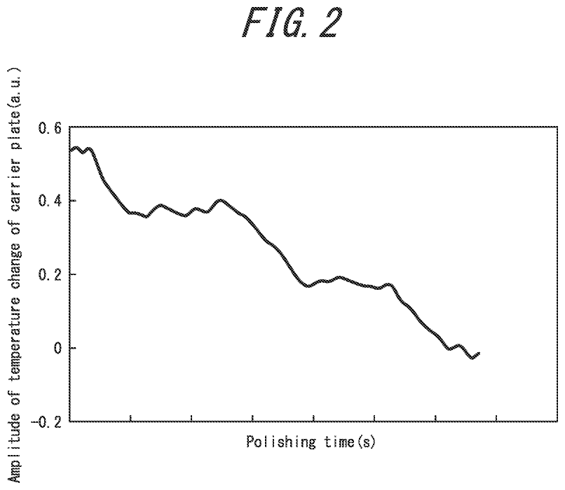

FIG. 3 is a diagram illustrating how the cross-sectional shapes of a carrier plate and a workpiece change while the workpiece is double-side polished repeatedly;

FIG. 4 is a diagram illustrating the offset time in this disclosure;

FIG. 5 is a diagram illustrating an example of a double-side polishing apparatus according to this disclosure; and

FIG. 6 is a diagram illustrating the distribution of the GBIR of silicon wafers for Conventional Example and Example 2.

### DETAILED DESCRIPTION

(Double-Side Polishing Apparatus)

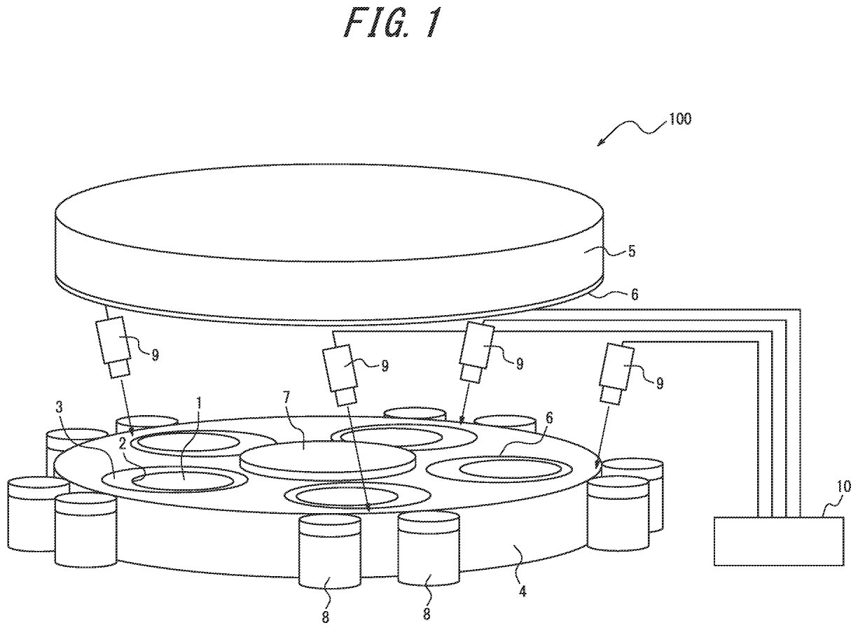

Embodiments of this disclosure will now be described with reference to the drawings. As described above, in the double-side polishing apparatus 100 disclosed in PTL 2 that is depicted in FIG. 1, the amount of polishing removal of the workpiece 1 by double-side polishing is controlled based on the amplitude of the temperature change of the carrier plate 3. According to the studies of the inventors of this disclosure, double-side polishing of the workpiece 1 is started using the freshly produced carrier plate 3 having high flatness, and in stages where the number of repetition of double-side polishing (that is, the number of batches) is small, double-side polishing can be terminated in the stage where the shape of the workpiece 1 becomes a desired shape. However, it was found that the shape of the workpiece 1 having been double-side polished is gradually deviated from the desired shape and is deteriorated as the number of repetition of double-side polishing (that is, the number of batches) increases.

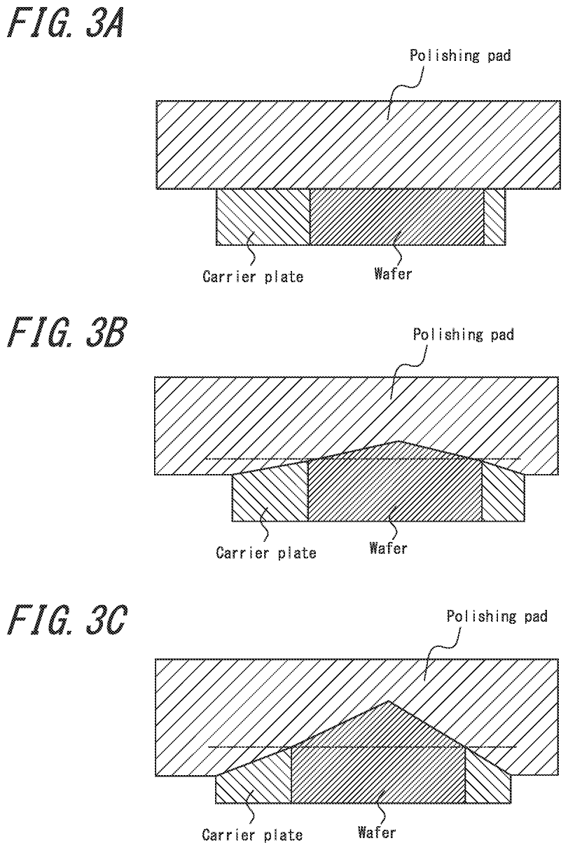

Specifically, when double-side polishing of the workpiece (for example, silicon wafer) 1 is performed using the freshly produced carrier plate 3, as illustrated in State (a) in FIG. 3, the workpiece 1 having a desired shape having high flatness can be obtained by terminating the double-side polishing at a time point determined based on the amplitude of the temperature change of the carrier plate 3, for example, at a time point where the amplitude becomes zero.

However, as double-side polishing of the workpiece 1 is repeated, due to the difference between the travel distances of the inner and outer peripheral portions of the carrier, the outer peripheral portion of the carrier plate 3 is polished by the polishing pad 6 more than the inner peripheral portion of the carrier plate 3. Thus, the flatness is worse in the outer peripheral portion. When the workpiece 1 is double-side polished using such a carrier plate 3 with reduced flatness, and the double-side polishing is terminated at a time point determined based on the amplitude of the temperature change of the carrier plate 3, for example, at a time point where the amplitude becomes zero; as illustrated in State (b) in FIG. 3, the shape of the workpiece 1 becomes a convex shape with poor flatness, thus the workpiece 1 having a desired shape cannot be obtained.

This being the case, when double-side polishing is further repeated using such a carrier plate 3 with reduced flatness, the flatness of the carrier plate 3 is reduced further as illustrated in State (c) in FIG. 3, and the shape of the workpiece 1 would also become worse.

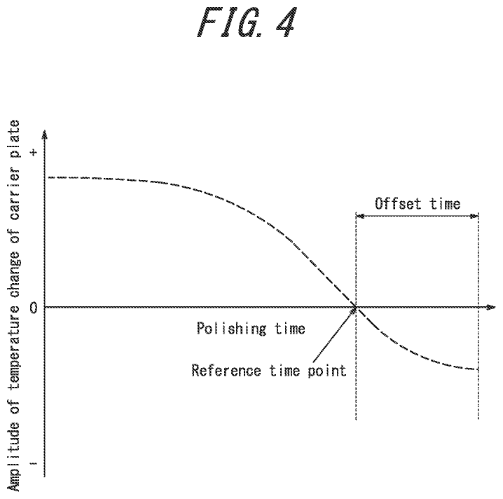

As such, when double-side polishing is terminated at a time point determined based on the amplitude of the temperature change of the carrier plate 3, as double-side polishing of the workpiece 1 is repeated, the double-side polishing cannot be terminated in the stage where the workpiece 1 comes to have a desired shape. Accordingly, in order that the workpiece 1 can have a desired shape, double-side polishing is required to be performed further for a predetermined time. Hereafter, as illustrated in FIG. 4, the time point at which the amplitude of the temperature change of the carrier plate 3 is zero is defined as a reference time point, and the time during which double-side polishing is additionally performed from the reference time point is referred to as “offset time”.

The inventors diligently studied how to determine the offset time so that double-side polishing can be terminated in a stage such that the workpiece 1 will have a desired shape. To that end, the relationship between the offset time and the shape index (specifically, GBIR) of the workpiece 1 after double-side polishing was analyzed in detail for different offset times. As a result, they found that the value of the shape index of the workpiece 1 to be double-side polished in the next batch can be predicted from the actual value of the shape index of the workpiece 1 having been double-side polished in a past batch that is the last batch or an earlier batch, and the difference between the offset times of batches (the difference between the offset time of the next batch and the offset time of the last batch).

As described above, as double-side polishing of the workpiece 1 is repeated, due to the difference between the travel distances of the inner and outer peripheral portions of the carrier, the outer peripheral portion of the carrier plate 3 is polished by the polishing pad 6 more than the inner peripheral portion of the carrier plate 3. Thus, the flatness is worse in the outer peripheral portion. The inventors considered that it was important to use the amount of change, that is, the difference, of the offset time as a parameter in order to predict the shape of the carrier plate 3 that changes every moment. Further, they found that the value of the shape index of the workpiece 1 to be double-side polished in the next batch could be predicted using the difference between the actual value of the shape index of the workpiece 1 having been double-side polished in a past batch that is the last batch or an earlier batch and the difference of the offset time between batches.

Subsequently, the inventors contemplated determining the above offset time based on the predicted value of the shape index of the workpiece to be double-polished in the next batch, predicted from the actual value of the shape index of the workpiece having been double-side polished in a past batch that is the last batch or an earlier batch and the difference of the offset time between batches. This led to the completion of this disclosure.

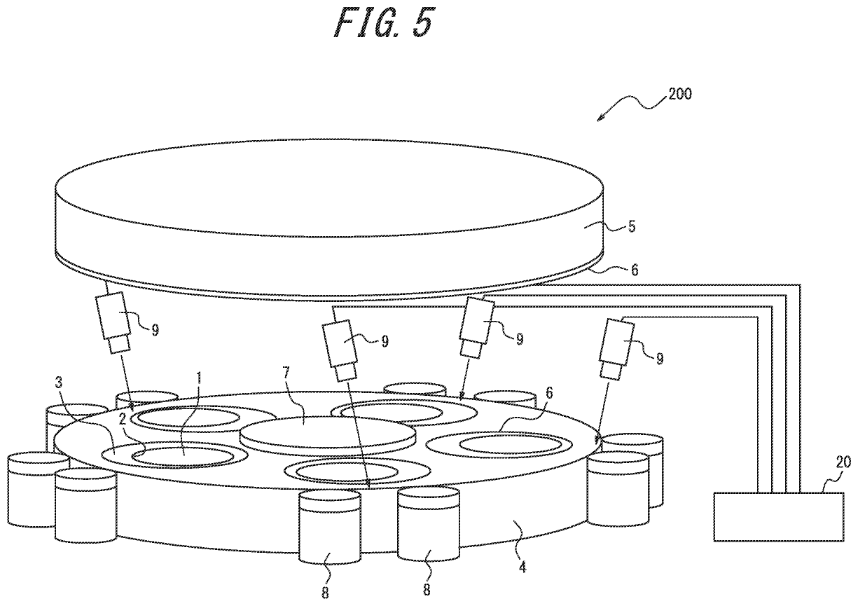

FIG. 5 illustrates an example of a double-side polishing apparatus according to this disclosure. Note that the same features of the double-side polishing apparatus 100 depicted in FIG. 1 and FIG. 5 are denoted by the same reference numerals. The difference between double-side polishing apparatus 100 disclosed in PTL 2 that is depicted in FIG. 1 and a double-side polishing apparatus 200 of this disclosure that is depicted in FIG. 5 is the structure of the control means 10 and 20. Specifically, in the double-side polishing apparatus 100 disclosed in PTL 2, the controller 10 is configured to terminate double-side polishing at a time point determined based on the amplitude of the temperature change of the carrier plate 3.

By comparison, in the double-side polishing apparatus 200 according to this disclosure, the control means 20 is configured to terminate double-side polishing of the workpiece 1 at a time point after a lapse of the offset time determined as described above from the reference time point determined by the control means 10 in the above double-side polishing apparatus 100. This can terminate double-side polishing of the workpiece 1 so that the workpiece has will have a desired shape even when double-side polishing of the workpiece 1 is performed repeatedly.

The inventors found that the predicted value Y of the shape index of the workpiece 1 of the next batch is given by the following equation (3):

Y=AX₁+BX₂+C (3),

where the actual value of the shape index (for example, GBIR) of the workpiece 1 in the last batch is X₁, the difference between the offset time of the next batch and the offset time of the last batch is X₂, and A, B, and C are constants.

The above equation (3) indicates that the objective variable, that is, the predicted value Y of the shape index of the workpiece 1 in the next batch can be calculated by multiple regression analysis using, as explanatory variables, the actual value X₁ of the shape index of the workpiece 1 in the last batch and the difference X₂ between the offset time of the next batch and the offset time of the last batch.

Using the above equation (3), as long as the difference X₂ between the offset time of the next batch and the offset time of the last batch, that is, how much the offset time is increased in the next batch from that of the last batch is determined, the value of the shape index of the workpiece 1 having been double-side polished in the next batch can be predicted.

In other words, when a target shape index of the next batch is determined and substituted into the left-hand side of the equation (3), the difference X₂ between the offset time of the next batch and the offset time of the last batch can be determined, such that the shape index of the workpiece 1 after the next double-side polishing becomes the target shape index, thus the offset time of the next batch can be determined. Further, the workpiece 1 having the target shape index can be obtained by performing additional double-side polishing for the determined offset time from the reference time point.

Note that when the offset time of the next batch is determined from the above equation (3), the difference X₂ between the offset time of the next batch and the offset time of the last batch, obtained from the equation (3) may be multiplied by a coefficient α (0<α≤1) thereby reducing the effect of the measurement error related to the actual value of the shape index of the workpiece 1. The value of a above may be set to, for example, 0.2.

Further, according to the studies made by the inventors, it was found for the above equation (3) that the predicted value Y of the shape index of the workpiece 1 in the next batch can be predicted more accurately by reducing the effect of variations of the relationship between the offset time and the shape index of the workpiece 1 by individually averaging X₁ and X₂ based on not only the last one batch but also a plurality of earlier batches.

Namely, the shape index of the workpiece 1 in the next batch can be more accurately predicted by using the average of the actual values of the shape indices of the last batch and a plurality of earlier batches as X₁ in the above equation (3), and using the average of the differences between the offset times between adjacent batches in the last batch and a plurality of earlier batches as X₂.

Further studies made by the inventors have indicated that taking the results of three batches up to three batches ago into considered, the predicted value Y of the shape index of the workpiece 1 in the next batch can be most accurately predicted. Specifically, in the above equation (3), the average of the actual values of the shape indices of three batches up to 3 batches ago is set to X₁, and the average of the differences between the offset times between batches is set to X₂. For example, the shape indices, for example, the values of GBIR, of the workpiece 1 in three batches ago, two batches ago, and the last batch are 80 nm, 70 nm, and 60 nm, respectively; and the offset times of three batches ago, two batches ago, the last batch, and the next batch are 50 s, 60 s, 80 s, and X s, respectively.

In such as case, X₁ in the equation (3) is expressed as X₁=(80+70+60)/3=70 s. Meanwhile, X₂=((60−50)+(80−60)+(X−80))/3=(X−50)/3 s. These X₁ and X₂ are substituted into the right-hand side of the equation (3), and a target GBIR of the next batch is substituted into Y; thus, the offset time X of the next batch can be determined. As demonstrated in Examples to be described below, using the results of three batches up to three batches ago, the shape index of the workpiece 1 in the next batch can be most accurately predicted, as compared with the case of using the result of only the last one batch.

In the above description, as a reference time point for determining the time point of termination of double-side polishing, the time point at which the amplitude of the temperature change of the carrier plate 3 becomes zero is used; and this disclosure is characterized by a method of determining the offset time from the reference time point. Hence, the reference time point itself is not required to be fixed to the time point at which the above amplitude of the temperature change of the carrier plate 3 becomes zero, and the reference time point may be a time point before the amplitude of the temperature change becomes zero.

In this case, for the determined time point before the amplitude of the temperature change of the carrier plate 3 becomes zero as the reference time point, the data of the shape indices of the workpiece with respect to different offset times are previously obtained. Further, an equation corresponding to the above equation (3) is found by multiple regression analysis, and using the equation found, the predicted value of the shape index of the workpiece in the next batch may be determined.

(Double-Side Polishing Method)

Next, a method of double-side polishing a workpiece will be described. In a method of double-side polishing a workpiece, according to this disclosure, the temperature of a carrier plate during double-side polishing is measured; a reference time point for determining a termination point of double-side polishing is determined based on the amplitude of the change of the measured temperature; an offset time for the next batch, that is, a time during which additional double-side polishing is performed is determined; and double-side polishing of the workpiece is terminated after a lapse of the determined offset time from the reference time point. Here, the offset time is determined based on a predicted value of the shape index of the workpiece to be double-side polished in the next batch, predicted from the actual value of the shape index of the workpiece having been double-side polished in one or more previous batches and from difference of the offset time between batches. Thus, double-side polishing of the workpiece can be terminated in such a manner that the workpiece will have a desired shape even when double-side polishing is performed repeatedly.

As described above, a predicted value Y of the shape index of the workpiece 1 of the next batch is given by the following equation (4):

Y=AX₁+BX₂+C (4),

where the actual value of the shape index (for example, GBIR) of the workpiece 1 in the last batch is X₁, the difference between the offset time of the next batch and the offset time of the last batch is X₂, and A, B, and C are constants.

As also described above, in the above equation (4), a predicted value Y of the shape index of the workpiece 1 of the next batch can be predicted most accurately when the average of the actual values of the shape indices of the workpiece 1, obtained in three batches up to three batches ago is X₁; and the average of the differences of the offset time between the batches is X₂.

The above reference time point may be a time point where the amplitude of the temperature change of the carrier plate 3 becomes zero or may be a time point before the amplitude of the temperature change becomes zero. Further, as the shape index of the workpiece 1, GBIR may be used. In this case, the value is negative when the workpiece 1 has a concave shape such that the height of the center portion of the workpiece 1 is smaller than the height of the outer peripheral portion, and the value is positive when the workpiece 1 has a convex shape such that the height of a center portion of the workpiece 1 is larger than the height of the outer peripheral portion.

### EXAMPLES

Examples will now be described in detail; however, this disclosure is not limited to the Examples.

### Conventional Example

Using the double-side polishing apparatus 100 depicted in FIG. 1, 1400 silicon wafers with a diameter of 300 mm were double-side polished. Specifically, the difference (X₂) of the offset time for the next batch was determined from the GBIR (X₁) actually obtained for a target value of GBIR (fixed value), and the offset time of the next batch was determined from the offset time of the previous batches by an operator based on his/her experience. With respect to silicon wafers having been double-side polished, the average and the distribution of the GBIRs, and the yield in cases where the GBIR was less than 200 nm are given in Table 1.

### Example 1

First, for different offset times, the actual value of the GBIRs of the silicon wafers having been double-side polished were determined, and the constants A, B, and C in the equation (3) were determined by multiple regression analysis using the actual value of the GBIR of the last batch and the difference between the offset time of the next batch and the offset time of the last batch as objective variables, and a predicted value of the GBIR in the next batch as an explanatory variable.

Next, using the double-side polishing apparatus 200 depicted in FIG. 5, 1400 silicon wafers with a diameter of 300 mm were double-side polished. Specifically, the difference (X₂) of the offset time for the next batch was determined from the GBIR (X₁) actually obtained for a target value of GBIR (fixed value), and the offset time of the next batch was determined from the offset time of the last batch using the equation (3). Here, the control means 20 set an offset time using the result of only the last batch. With respect to silicon wafers having been double-side polished, the average and the distribution of the GBIRs, and the yield in cases where the GBIR was less than 200 nm are given in Table 1.

### Example 2

Double-side polishing was performed in the like manner as in Example 1. However, when the GBIR of the silicon wafers of the next batch was predicted from the equation (3), the results of the batches up to three batches ago were used. All the other conditions were the same as those in Example 1. With respect to silicon wafers having been double-side polished, the average and the distribution of the GBIRs, and the yield in cases where the GBIR was less than 200 nm are given in Table 1.

### Example 3

Double-side polishing was performed in the like manner as in Example 1. However, when the GBIR of the silicon wafers of the next batch was predicted from the equation (3), the results of the batches up to five batches ago were used. All the other conditions were the same as those in Example 1. With respect to silicon wafers having been double-side polished, the average and the distribution of the GBIRs, and the yields of the cases where the GBIR was less than 200 nm are given in Table 1.

TABLE 1

| | Conventional | Examples | | |
|---|---|---|---|---|
| | Example | Example 1 | Example 2 | Example 3 |
| Number of batches | — | 1 | 3 | 5 |
| considered | | | | |
| Average of GBIR (nm) | 134 | 127 | 121 | 130 |
| Distribution of | 32 | 30 | 27 | 32 |
| GBIR (nm) | | | | |
| Yield (%, GBIR < 200 | 96.9 | 97.2 | 98.9 | 97.0 |
| nm) | | | | |

As is evident from Table 1, in Examples 1 to 3, the average of the GBIRs is lower than in Conventional Example; and in Examples 1 and 2, the distribution of GBIRs is also smaller. Further, the yield in cases where the GBIR was less than 200 nm was also improved as compared with Conventional Example. Comparison of Examples 1 to 3 indicates that the average and the distribution of the GBIRs are minimum in the case of Example 2 in which the number of batches taken into consideration was three, and the yield was maximum in this case.

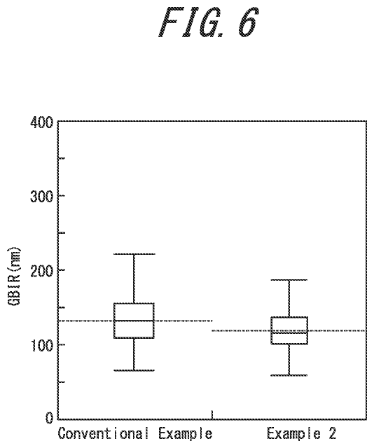

FIG. 6 illustrates the distribution of the GBIRs of the silicon wafers for Conventional Example and Example 2. As is evident from FIG. 6 and Table 1, the average of the GBIRs in Example 2 was smaller than that in Conventional Example by 13 nm, and the variation in the GBIR was also small; in addition, the yield was improved by as high as 2%.

For four double-side polishing apparatuses, the GBIRs of silicon wafers having been double-side polished were determined with respect to different offset times. Subsequently, the constants A, B, and C in the equation (3) were determined by multiple regression analysis using the GBIR of the last batch and the difference of the offset time between batches, which had been determined, as objective variables, and a predicted value of the GBIR in the next batch as an explanatory variable. Here, the results of the batches before three batches ago were used. The values of A, B, and C obtained are given in Table 1. Note that the unit of X₁ in the equation (3) is in nm, and the unit of X₂ is in seconds.

TABLE 2

| | A | B | C |
|---|---|---|---|
| Apparatus No. 1 | 0.913501 | −0.000471 | 0.003866 |
| Apparatus No. 2 | 0.869789 | −0.00038 | 0.00303 |
| Apparatus No. 3 | 0.820903 | −0.000345 | 0.006655 |
| Apparatus No. 4 | 0.886185 | −0.001093 | 0.005433 |

As is evident from Table 2, the constants A, B, and C in the equation (3) depended on the double-side polishing apparatuses. This indicates that it is important to derive the equation (3) by determining the shape indices of silicon wafers having double-side polished with respect to different offset times determined using the double-side polishing apparatuses.

### INDUSTRIAL APPLICABILITY

According to this disclosure, double-side polishing of a workpiece can be terminated so that the workpiece will have a desired shape even when double-side polishing of the workpiece is performed repeatedly, thus, this method is useful in the semiconductor wafer manufacturing industry.

### REFERENCE SIGNS LIST

1: Workpiece
2: Retainer opening
3: Carrier plate
4: Lower polishing plate
5: Upper polishing plate
6: Polishing pad
7: Sun gear
8: Internal gear
9: Temperature measurement means
10: Control means
100, 200: Double-side polishing apparatus

1. An apparatus for double-side polishing a workpiece, including a carrier plate in which one or more retainer openings each for retaining a workpiece to be polished are formed, and an upper polishing plate and a lower polishing plate that make a pair between which the carrier plate is sandwiched, comprising:
a temperature measurer that measures a temperature of the carrier plate; and
a controller that controls an amount of polishing removal of the workpiece,
wherein the controller determines, from a reference time point for determining a termination point of double-side polishing determined based on amplitude of change of temperature of the carrier plate measured using the temperature measurer, an offset time for a next batch that is a time during which additional double-side polishing is performed; and terminates double-side polishing of the workpiece after a lapse of the determined offset time from the reference time point, and
the offset time is determined based on a predicted value of a shape index of the workpiece to be double-side polished in the next batch, predicted from an actual value of a shape index of the workpiece having been double-side polished in one or more previous batches and from difference of the offset time between batches.

2. The apparatus for double-side polishing a workpiece, according to claim 1, wherein the predicted value is given by the following equation (1):
Y=AX₁+BX₂+C (1),
where the predicted value is Y, the actual value of the shape index is X₁, the difference of the offset time is X₂, and A, B, and C are constants.

3. The apparatus for double-side polishing a workpiece, according to claim 2, wherein an average of actual values of shape indices of the workpiece, obtained in three batches up to three batches ago is X₁; and an average of the differences of the offset time between batches is X₂.

4. The apparatus for double-side polishing a workpiece, according to claim 1, wherein the reference time point is a time point when the amplitude of the temperature change of the carrier plate becomes zero.

5. The apparatus for double-side polishing a workpiece, according to claim 1, wherein the reference time point is a time point before when the amplitude of the temperature change of the carrier plate becomes zero.

6. The apparatus for double-side polishing a workpiece, according to claim 1, wherein the shape index is a GBIR.

7. A method of double-side polishing a workpiece, including sandwiching, between an upper polishing plate and a lower polishing plate, a carrier plate in which one or more retainer openings each for retaining a workpiece to be polished are formed, with one or more workpieces being held in the carrier plate; and simultaneously polishing both surfaces of the workpieces by relatively rotating the carrier plate and the upper and lower polishing plates, comprising:
measuring temperature of the carrier plate during double-side polishing, thereby determining a reference time point for determining a termination point of double-side polishing determined based on amplitude of change of the temperature measured; and
determining, from the reference time point, an offset time for a next batch that is a time during which additional double-side polishing is performed, and terminating double-side polishing of the workpieces after a lapse of the determined offset time from the reference time point,
wherein the offset time is determined based on a predicted value of a shape index of the workpiece to be double-side polished in the next batch, predicted from an actual value of a shape index of the workpiece having been double-side polished in one or more previous batches and from difference of the offset time between batches.

8. The method for double-side polishing a workpiece, according to claim 7, wherein the predicted value is given by the following equation (2):
Y=AX₁+BX₂+C (2),
where the actual value of the shape index is X₁, the difference of the offset time is X₂, and A, B, and C are constants.

9. The method of double-side polishing a workpiece, according to claim 8, wherein an average of actual values of shape indices of the workpiece, obtained in three batches up to three batches ago is X₁; and an average of the differences of the offset time between batches is X₂.

10. The method of double-side polishing a workpiece, according to claim 7, wherein the reference time point is a time point when the amplitude of the temperature change of the carrier plate becomes zero.

11. The method of double-side polishing a workpiece, according to claim 7, wherein the reference time point is a time point before when the amplitude of the temperature change of the carrier plate becomes zero.

12. The method of double-side polishing a workpiece, according to claim 7, wherein the shape index is a GBIR.
